(19) United States
(12) Patent Application Publication
(10) Pub. No.: US 2007/0193512 A1
(43) Pub. Date: Aug. 23, 2007

(54) Plasma generating method, plasma generating apparatus, and plasma processing apparatus

(75) Inventors: Hiroshige Deguchi, Kyoto (JP); Hitoshi Yoneda, Kyoto (JP); Kenji Kato, Kyoto (JP); Akinori Ebe, Kyoto (JP); Yuichi Setsuhara, Osaka (JP)

Correspondence Address: FINNEGAN, HENDERSON, FARABOW, GARRETT & DUNNER;LLP, 901 NEW YORK AVENUE, NW, WASHINGTON, DC, 20001-4413, US

(73) Assignee: NISSIN ELECTRIC CO., LTD. and EMD CORPORATION

(21) Appl. No.: 11/707,862

(22) Filed: Feb. 20, 2007

(30) Foreign Application Priority Data
Feb. 20, 2006 (JP) P.2006-042316

(51) Int. Cl. C23C 16/00

(52) U.S. Cl. 118/723 I

(57) ABSTRACT

One or more high-frequency antennas is allocated to and disposed in one cubic space C having a side of 0.4 [m] in a plasma generating chamber 1 or in each of plural cubic spaces C, each having a side of 0.4 [m], adjacent ones of the plural cubic spaces being continuous to each other without forming a gap therebetween. The total length L [m] of the high-frequency antennas in each of the cubic spaces C is set in a range which satisfies relationships of (0.2/P)<L<(0.8/P) with respect to an inductively coupled plasma generation pressure P [Pa] which is set in the plasma generating chamber 1.

### TECHNICAL FIELD

The present disclosure relates to a plasma generating method and apparatus for generating gas plasma, and also to a plasma processing apparatus which uses such a plasma-generating apparatus, or a plasma processing apparatus which applies a desired process on a workpiece under plasma.

### Related Art

A plasma generating apparatus is used various apparatuses using plasma, such as: a plasma CVD apparatus which forms a film under plasma; an apparatus which sputters a sputter target under plasma to form a film; a plasma etching apparatus which performs etching under plasma; an apparatus which extracts ions from plasma to perform ion implantation or ion doping; and an apparatus which uses the above-mentioned apparatus to produce various semiconductor devices (for example, thin film transistors used in a liquid crystal device or the like), material substrates for such semiconductor devices, and the like.

As a method and apparatus for generating gas plasma, various types are known such as those in which capacitively coupled plasma is generated, in which inductively coupled plasma is generated, in which ECR (Electron Cyclotron Resonance) plasma is generated, and in which microwave plasma is generated.

Among the above apparatuses and methods, the method and apparatus for generating plasma in which inductively coupled plasma is generated are configured so that, in order that uniform plasma the density of which is as high as possible is obtained in a plasma generating chamber, a high-frequency antenna is disposed in the plasma generating chamber, and a high-frequency electric power is applied to a gas in the chamber by the high-frequency antenna, thereby generating inductively coupled plasma.

Such a high-frequency antenna is sometimes disposed outside a plasma generating chamber. It has been proposed that a high-frequency antenna is placed in a plasma generating chamber for purposes of, for example, improving the use efficiency of an introduced high-frequency electric power.

For example, Japanese Patent Unexamined Publication No. 2001-35697 (Patent Reference 1) discloses a configuration in which, in order to improve the use efficiency of an introduced high-frequency electric power, a high-frequency antenna is placed in a plasma generating chamber.

The case where high-frequency antennas are disposed in a plasma generating chamber as described above, and a high-frequency electric power is applied to a gas in the plasma generating chamber by the high-frequency antennas, thereby generating inductively coupled plasma will be considered. In related art, the distribution and physical quantities (particularly, the lengths of the antennas) in the plasma generating chamber of the high-frequency antennas which enable plasma to be uniformly generated and maintained as far as possible in a space of a desired size in the plasma generating chamber, more specifically, the sizes of subspaces obtained by partitioning the desired-size space in which plasma is to be generated as uniformly as possible and maintained, and the lengths of the antennas which are allocated to the subspaces are determined in the following manner.

A process of cutting an antenna material and placing as a trial the cut material in the plasma generating chamber (so-called cut and try by actual alignment) is repeatedly performed. When distribution and physical quantities of antennas by which plasma can be uniformly generated and maintained are once found as result of the cut and try, the distribution and quantities are deemed as satisfactory.

In the technique in which, when distribution and physical quantities of antennas by which plasma can be generated and maintained are once found as result of the cut and try, the distribution and quantities are deemed as satisfactory, the number and whole length of antennas tend to be larger as compared to distribution and physical quantities of antennas by which plasma can be uniformly generated and maintained, and which are economical and adequate.

When the number of antennas is large, places through which the antennas are inserted into the plasma generating chamber are increased. Therefore, the gas tightness of the plasma generating chamber is lowered, and a larger amount of unwanted particles are produced by rubbing at the insertion places, and the like. As a result, the performance of the apparatus for generating plasma is easily lowered. In order to prevent this from occurring, disposition of antennas requires much labor and cost. When the number or whole length of antennas is excessively large, the cost is correspondingly increased, and therefore such an apparatus is uneconomical.

### SUMMARY

Embodiments of the present invention provide a plasma generating method and apparatus which can generate uniformized inductively coupled plasma in an economical manner.

Further, embodiments of the present invention provide a plasma processing apparatus wherein plasma can be economically generated, and a desired process on a workpiece can be performed in a correspondingly economical manner.

The inventors have conducted researches in order to attain the objects, and noted the following points.

When the number of antennas is increased, there is a tendency in which plasma is easily maintained. When the sizes (whole lengths) of antennas are made large, there is a tendency in which plasma is easily maintained.

Such a plasma maintaining characteristics depend on the number and sizes of antennas and the plasma generation pressure.

In the case where the number and sizes of antennas, and the plasma generation pressure can be unifiedly handled, when the plasma generation pressure which is defined to some extent by the seed gas serving as the source of plasma, and the like is selected and determined, the number and sizes of antennas can be determined adequately (just enough as far as possible) so as to enable plasma to be generated and maintained, and hence this case is economical.

In the case where the number and sizes of antennas, and the plasma generation pressure are unifiedly handled, among parameters, a parameter in which the unit of measure is meters is the total length of antennas in the plasma generating chamber, or in other words a space of a constant restricted size.

The inventors have conducted further researches, and found that an inverse proportional relationship exists between the total length L [m] of high-frequency antennas in a space of a constant restricted size and the plasma generation pressure [Pa] in the space. Furthermore, it has been found that, when the total length L [m] of high-frequency antennas in a space of a constant restricted size is set so as to satisfy relationships of (0.2/P)<L<(0.8/P) with respect to an inductively coupled plasma generation pressure P [Pa] in the space, it is possible to perform an economical antenna design which enables plasma to be generated and maintained.

In consideration of the range of the plasma generation pressure which is usually employed in accordance with the seed gas serving as the source of plasma, and the like, when L is shorter than (0.2/P), the total length L of the antennas is insufficient, so that plasma is hardly generated and maintained. When L is longer than (0.8/P), the total length L of the antennas is unnecessarily prolonged, and the resulting product is uneconomical.

Therefore, the range of L is approximately set to (0.2/P)<L<(0.8/P).

By contrast, it is usually desired that, in addition to generation and maintaining of plasma, plasma is generated as uniformly as possible in a space of a desired size in the plasma generating chamber.

According to researches by the inventors, the plasma density can be well approximated by a function in which the density exponentially attenuates in accordance with the distance from an antenna.

In view that, as described above, the plasma density can be well approximated by a function in which the density exponentially attenuates in accordance with the distance from an antenna, in the case where plural antennas are disposed in a space of a desired size in the plasma generating chamber in order to generate plasma in the space, when the interval between adjacent antennas is excessively large, the plasma density in the space of a desired size tends to become nonuniform. By contrast, when the interval between adjacent antennas is reduced, the physical quantities of the antennas are unnecessarily increased.

With using the characteristics that, as described above, the plasma density can be well approximated by a function in which the density exponentially attenuates in accordance with the distance from an antenna, the inventors have obtained the plasma density distribution in the case where plural antennas are arranged at a constant arrangement pitch. As a result, it has been found that, when the arrangement pitch of antennas is excessively large, the plasma density distribution tends to be nonuniform, and, when the arrangement pitch of antennas is set to about 400 mm, uniform plasma can be obtained without unnecessarily increasing the number of the antennas.

Base on this finding, it has been further found that, when, in accordance with the size of a space in a plasma generating chamber in which plasma is to be generated, a high-frequency antenna is disposed in one cubic space having a side of 0.4 [m] in the plasma generating chamber or in each of plural cubic spaces in the plasma generating chamber, each having a side of 0.4 [m], adjacent ones of aid plural cubic spaces being continuous to each other, uniform plasma can be obtained without unnecessarily increasing physical quantities of the antennas.

It has been further found that, when the total length L of the high-frequency antennas disposed in a cubic space having a side of 0.4 [m] is set so as to satisfy the above-mentioned relationships of (0.2/P)<L<(0.8/P) for enabling plasma to be generated and maintained in a constant space, uniform plasma can be generated and maintained as a whole.

According to one or more embodiments of the invention, the following method and apparatus for generating plasma are provided on the basis of the above-mentioned observation and finding.

(1) Method of Generating Plasma

A plasma generating method generates inductively coupled plasma by disposing a high-frequency antenna in a plasma generating chamber, and applying a high-frequency electric power to a gas in the plasma generating chamber by the high-frequency antenna. In the plasma generating method, the high-frequency antenna is allocated to and disposed in one cubic space having a side of 0.4 [m] in the plasma generating chamber or each of plural cubic spaces in the plasma generating chamber, each having a side of 0.4 [m], adjacent ones of the plural cubic spaces being continuous to each other without forming a gap therebetween. Further, a total length L [m] of the high-frequency antennas in each of the cubic spaces is set in a range which satisfies relationships of (0.2/P)<L<(0.8/P) with respect to an inductively coupled plasma generation pressure P [Pa] that is set in the plasma generating chamber.

(2) Apparatus for Generating Plasma

A plasma generating apparatus generates inductively coupled plasma by disposing a high-frequency antenna in a plasma generating chamber, and applying a high-frequency electric power to a gas in the plasma generating chamber by the high-frequency antenna. In the plasma generating apparatus, the high-frequency antenna is allocated to and disposed in one cubic space having a side of 0.4 [m] in the plasma generating chamber or each of plural cubic spaces in the plasma generating chamber, each having a side of 0.4 [m], adjacent ones of the plural cubic spaces being continuous to each other without forming a gap therebetween. Further, a total length L [m] of the high-frequency antennas in each of the cubic spaces is set in a range which satisfies relationships of (0.2/P)<L<(0.8/P) with respect to an inductively coupled plasma generation pressure P [Pa] that is set in the plasma generating chamber.

According to the method and apparatus for generating plasma, a plasma generation pressure P [Pa] (not particularly restricted, but in a range of about 0.05 to 10 Pa) which is defined by the seed gas serving as the source of plasma, and the like is selected and determined, and in accordance with the space of a desired size in the plasma generating chamber, or in other words a space in which inductively coupled plasma is to be generated, such as a space in which inductively coupled plasma for applying a desired plasma process on a substrate is to be generated, and the size of which corresponds to that of the substrate, one cubic space having a side of 0.4 [m] or plural cubic spaces having a side of 0.4 [m] and adjacently continuous to one another without forming a gap therebetween are defined. Furthermore, a high-frequency antenna is disposed in each of the cubic spaces, the total length L [m] of the high-frequency antennas in the cubic spaces is set in a range which satisfies relationships of (0.2/P)<L<(0.8/P) with respect to an inductively coupled plasma generation pressure P [Pa] in the plasma generating chamber, whereby inductively coupled plasma can be uniformly generated and maintained.

At this time, the high-frequency antenna(s) is disposed while setting as a unit the space of a desired size in the plasma generating chamber, or in other words the cubic space having a side of 0.4 [m] that is defined so as to correspond to a space having a size in which inductively coupled plasma is to be generated. Therefore, the distribution of the high-frequency antennas can be determined easily, just enough, and adequately. Since the total length L [m] of the high-frequency antennas in the cubic spaces is set so as to satisfy the relationships of (0.2/P)<L<(0.8/P), the lengths of the antennas are determined easily and economically. Therefore, inductively coupled plasma can be generated in a correspondingly economical manner.

The antennas are adequately distributed, and therefore places through which the antennas are inserted into the plasma generating chamber are prevented from being increased. Therefore, reduction of the gas tightness of the plasma generating chamber, and production of unwanted particles due to rubbing at the insertion places, and the like are suppressed.

An example of the high-frequency antenna is a two-dimensional antenna (antenna having a planar structure) which is ended without making one turn. For example, an antenna which is formed by bending a linear conductor (into a U-like shape, a portal shape, or the like) may be used.

One or plural high-frequency antennas may be disposed in one cubic space having a side of 0.4 [m]. However, the total length L [m] of the high-frequency antenna(s) in the cubic space is set in a range which satisfies the relationships of (0.2/P)<L<(0.8/P).

Typically, the disposition of high-frequency antenna in the cubic space having a side of 0.4 [m] may be performed by disposing the high-frequency antenna in a middle portion of the cubic space. When a high-frequency antenna is disposed in each of plural cubic spaces continuous to one another, the antennas may be typically disposed in middle portions of the cubic spaces, respectively, and more preferably may be disposed in the same direction.

Of course, such antenna disposition in a cubic space is applied to the case where one high-frequency antenna is disposed in one cubic space. In the case where plural high-frequency antennas are disposed in a cubic space having a side of 0.4 [m], a group of plural high-frequency antennas may be deemed as a whole as one high-frequency antenna, and the high-frequency antenna group which is deemed as one high-frequency antenna may be disposed in, for example, a middle portion of the cubic space.

One or more embodiments of the invention provides a plasma processing apparatus which applies a desired process on a workpiece under plasma, wherein the apparatus includes the above-mentioned plasma generating apparatus according to one or more embodiments of invention.

The plasma processing apparatus of one or more embodiments of the invention uses the plasma generating apparatus according to one or more embodiments of the invention, and can economically generate plasma. Therefore, a desired process on a workpiece can be performed in a correspondingly economically manner.

Examples of such a plasma processing apparatus are various apparatus using plasma such as: a plasma CVD apparatus; an apparatus which sputters a sputter target under plasma to form a film; an etching apparatus using plasma; an apparatus which extracts ions from plasma to perform ion implantation or ion doping; and an apparatus which uses the above-mentioned apparatus and produces various semiconductor devices (for example, thin film transistors used in a liquid crystal device or the like), material substrates for such semiconductor devices, and the like.

One or more embodiments of the present invention may include one or more the following advantages. For example, it is possible to provide a plasma generating method of generating inductively coupled plasma by disposing a high-frequency antenna in a plasma generating chamber, and applying a high-frequency electric power to a gas in the plasma generating chamber by the high-frequency antenna, wherein the distribution and lengths of the high-frequency antennas, which are adequate for enabling plasma to be uniformly generated and maintained, in the plasma generating chamber can be suitably determined, and uniformized inductively coupled plasma can be generated in a correspondingly economical manner.

Furthermore, it is possible to provide a plasma generating apparatus which generates inductively coupled plasma by disposing a high-frequency antenna in a plasma generating chamber, and applying a high-frequency electric power to a gas in the plasma generating chamber by the high-frequency antenna, wherein the distribution and lengths of the high-frequency antennas, which are adequate for enabling plasma to be uniformly generated and maintained, in the plasma generating chamber can be suitably determined, and uniformized inductively coupled plasma can be generated in a correspondingly economical manner.

Moreover, it is possible to provide a plasma processing apparatus wherein plasma can be economically generated, and a desired process on a workpiece can be performed in a correspondingly economical manner.

Other features and advantages may be apparent from the following detailed description, the accompanying drawings and the claims.

### BRIEF DESCRIPTION OF THE DRAWINGS

FIG. 1 is a diagram showing an example of the apparatus for generating plasma of the invention.

FIG. 2 is a diagram showing another example of the apparatus for generating plasma of the invention.

FIGS. 3(A) to 3(E) are diagrams exemplary showing antenna arrangements and power supply portions in the case where plural high-frequency antennas are used.

FIG. 4 is a graph showing a result of an experiment of measuring a plasma maintaining lower-limit pressure in which antennas of different numbers and sizes are used.

FIG. 5 is a graph showing relationships between the total length of antennas and the plasma maintaining lower-limit pressure, obtained on the basis of the experiment result shown in FIG. 4.

FIG. 6 is a graph showing examples of relationships between an ion saturation current density [A/cm²] and the distance X [m] from an antenna.

FIG. 7 is a diagram showing a further example of the apparatus for generating plasma of the invention.

FIG. 8 is a diagram showing an example (a plasma CVD apparatus) of the plasma processing apparatus of the invention.

### DETAILED DESCRIPTION

Hereinafter, one or more embodiments of the invention will be described with reference to the accompanying drawings.

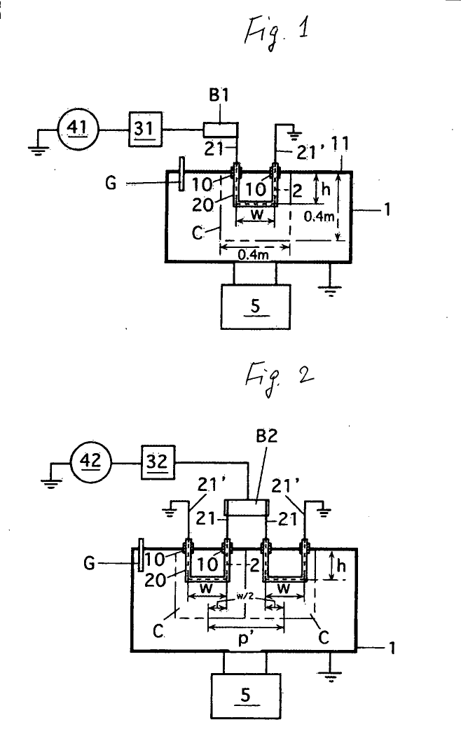

FIG. 1 shows an example of the apparatus for generating plasma of the invention, and FIG. 2 shows another example of the apparatus for generating plasma of the invention.

The plasma generating apparatus of FIG. 1 comprises a plasma generating chamber 1. One high-frequency antenna 2 is inserted from a ceiling wall 11 of the plasma generating chamber 1 into the interior of the chamber. The high-frequency antenna is covered by an insulative member 20, and passed together with the member 20 through insulative members 10 disposed in the ceiling wall 11. In the example, the antenna 2 has a portal shape.

In the plasma generating apparatus of FIG. 1, portions 21, 21′ of the antenna 2 are projected from the ceiling wall 11, and one portion 21 is connected to a feeder busbar B1. The busbar B1 is connected to a high-frequency power source 41 through a matching box 31. The other portion 21′ is grounded.

Also the plasma generating apparatus of FIG. 2 comprises a plasma generating chamber 1. Two high-frequency antennas 2 are inserted from a ceiling wall 11 of the plasma generating chamber 1 into the interior of the chamber. In the same manner as the antenna of FIG. 1, each of the high-frequency antennas is covered by an insulative member 20, and passed together with the member 20 through insulative members 10 disposed in the ceiling wall 11.

In the same manner as the antenna of FIG. 1, the antennas 2 in the plasma generating apparatus of FIG. 2 have a portal shape. The two antennas 2 have the same size, and are adjacent to each other in the same plane and in a series manner while forming a pitch interval p′ (in the example, 400 mm).

In the plasma generating apparatus of FIG. 2, portions 21, 21′ of each of the antennas 2 are projected to the outside of the chamber, and the portions 21, 21 which are adjacent to each other are connected to a common feeder busbar B2. The busbar is connected to a high-frequency power source 42 through a matching box 32. The other portions 21′ of the antennas 2 are grounded.

Both the plasma generating apparatuses of FIGS. 1 and 2 comprise a gas introducing section G through which a predetermined gas is introduced into the plasma generating chamber 1, and an evacuating apparatus 5 which evacuates the chamber interior to set the chamber interior to a predetermined plasma generation pressure.

The antenna 2 will be described again. In both the plasma generating apparatuses of FIGS. 1 and 2, each of the antennas 2 is configured by a conductive pipe member. The insulative member 20 which covers the antenna 2 is an insulative pipe.

In the example, the conductive pipe member which constitutes the antenna 2 is a copper pipe having a circular section shape. However, the invention is not restricted to this, and the pipe member may be made of another conductive material such as aluminum. The antenna is not required to be formed by a pipe member, and may be formed by, for example, a rod member made of a conductive material such as copper or aluminum, and having a circular section shape or the like.

In the example, the insulative pipe which covers the antenna 2 is a quartz pipe. However, the invention is not restricted to this, and the pipe member may be made of another insulative material such as alumina. The insulative member 20 is not required to be formed by a pipe member, and may be formed by coating the antenna 2 with an insulative material.

In the plasma generating apparatus of FIG. 1, the one antenna 2 is positioned in a middle portion of a cubic space C in the plasma generating chamber 1, having a side of 0.4 [m], and corresponding to a space where plasma is to be generated. The whole length L [m] (width w+height h×2) of the antenna is determined so as to satisfy relationships of (0.2/P)<L<(0.8/P) with respect to the plasma generation pressure P [Pa] which is set when desired inductively coupled plasma is to be generated in the chamber 1.

In the plasma generating apparatus of FIG. 2, the two antennas 2 are positioned respectively in middle portions of two cubic spaces C in the plasma generating chamber 1, having a side of 0.4 [m], continuous to one another in the same plane without forming a gap therebetween, and corresponding to a space where plasma is to be generated. The whole length L [m] (width w+height h×2) of each of the antennas 2 is determined so as to satisfy relationships of (0.2/P)<L<(0.8/P) with respect to the plasma generation pressure P [Pa] which is set when desired inductively coupled plasma is to be generated in the chamber 1.

In the above-described plasma generating apparatuses shown in FIGS. 1 and 2, the plasma generating chamber 1 is evacuated by the evacuating apparatus 5 to reduced the pressure in the chamber to be lower than the predetermined plasma generation pressure, and a high-frequency electric power is supplied from the high-frequency power source to the antenna(s) 2 while introducing the predetermined gas from the gas introducing section G into the chamber 1, and setting and maintaining the chamber interior to the predetermined plasma generation pressure P[Pa] by the evacuating apparatus 5, whereby uniform inductively coupled plasma can be generated and maintained in a region of the cubic space(s) C having a side of 0.4 [m] in the chamber 1. In the apparatus of FIG. 2, uniform inductively coupled plasma can be generated and maintained in the whole of the two cubic spaces C which are adjacently continuous to each other.

As described above, in the plasma generating apparatus of FIG. 1, the whole length L which satisfies the relationships of (0.2/P)<L<(0.8/P) is determined with respect to the one antenna 2, and the one antenna 2 having the whole length is employed, whereby uniform inductively coupled plasma can be generated and maintained easily and economically. Furthermore, the one antenna 2 is disposed in the cubic space C, and the whole length L of the antenna 2 satisfies the relationships of (0.2/P)<L<(0.8/P), whereby the one antenna 2 having a just enough and adequate whole length which enables uniformized plasma to be generated and maintained can be employed. Therefore, plasma is generated in a correspondingly economical manner.

Also in the plasma generating apparatus of FIG. 2, the antenna length L which satisfies the relationships of (0.2/P)<L<(0.8/P) is determined with respect to each of the two antennas 2, and the antennas 2 having the length are disposed in the cubic spaces C, respectively, whereby uniform inductively coupled plasma can be generated and maintained easily and economically. Furthermore, the antennas 2 are disposed in the cubic spaces C, respectively, and each of the antennas 2 satisfies the relationships of (0.2/P)<L<(0.8/P), whereby the two antennas 2 having an adequate number and a just enough and adequate length which enables uniformized plasma to be generated and maintained, and adequate distribution of the antennas can be employed. Therefore, plasma is generated in a correspondingly economical manner.

Next, the process of the finding that the relationships of (0.2/P)<L<(0.8/P) can be applied in determination of physical quantities of the antenna(s) will be described.

First, experiments of checking relationships between the number of antennas and the lower-limit pressure [Pa] at which plasma can be maintained (hereinafter referred as plasma maintaining lower-limit pressure) were performed while variously changing the number of antennas, the whole length (width w+height h×2 in the chamber 1) of each of the antennas in the plasma generating chamber, and the pitch interval p (arrangement pitch of antennas) of adjacent antennas in the case where plural antennas are arranged.

In the experiments, the antenna setting conditions and the plasma generation pressure were variously changed in the plasma generating apparatus of FIG. 1 or 2. A chamber having a capacity of 0.5 m³ was used as the plasma generating chamber 1, hydrogen gas was introduced as the plasma source gas into the chamber, and a high-frequency electric power of 13.56 MHz and 1,000 W was supplied to each of the antennas. After the pressure in the chamber was raised and electric discharge was started, the pressure in the chamber was lowered, and the pressure at a timing when the power reflected to the matching box was destabilized was determined as the plasma maintaining lower-limit pressure [Pa]. As the plasma generating pressure in the chamber is lower, discharge is maintained more hardly.

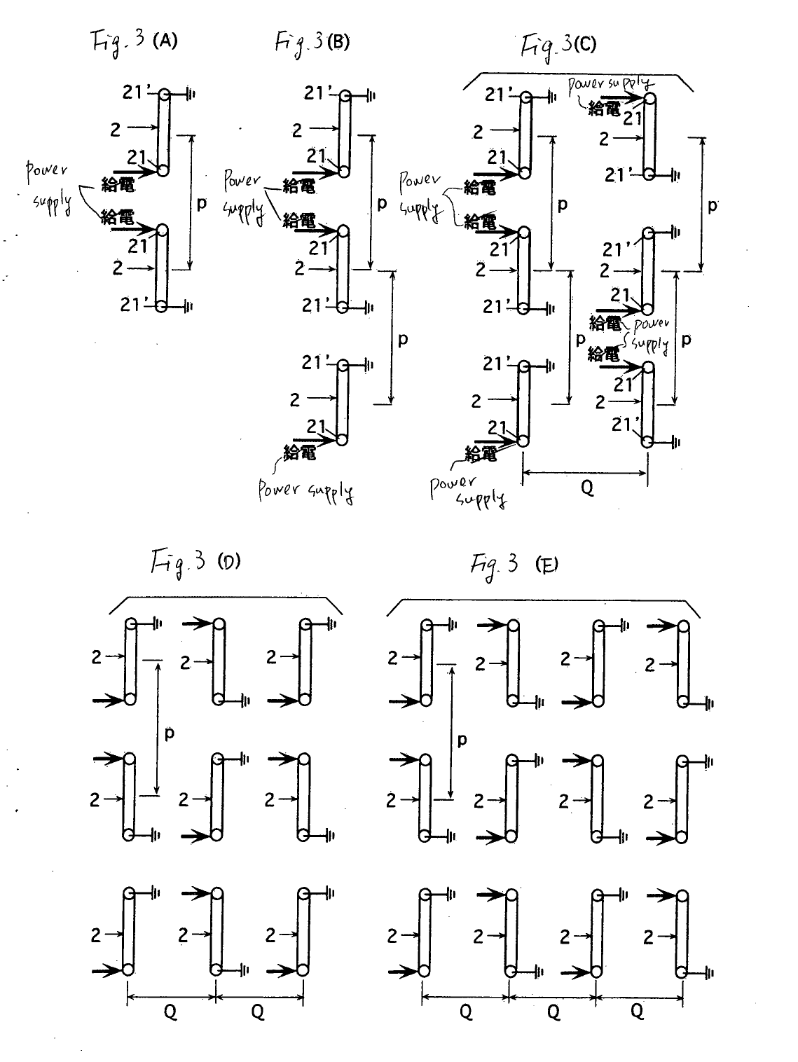

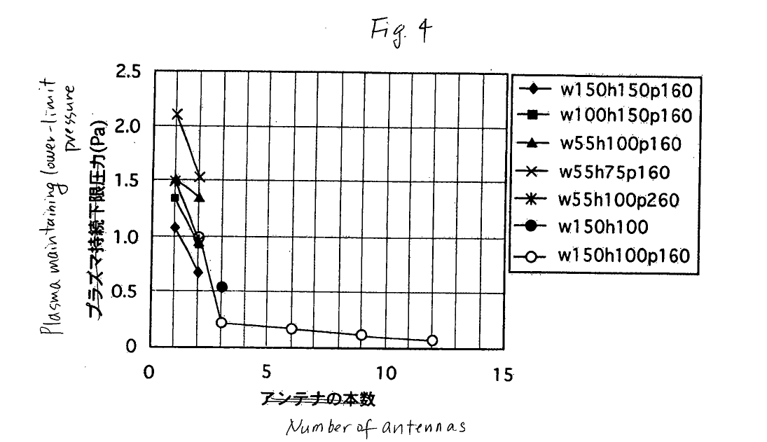

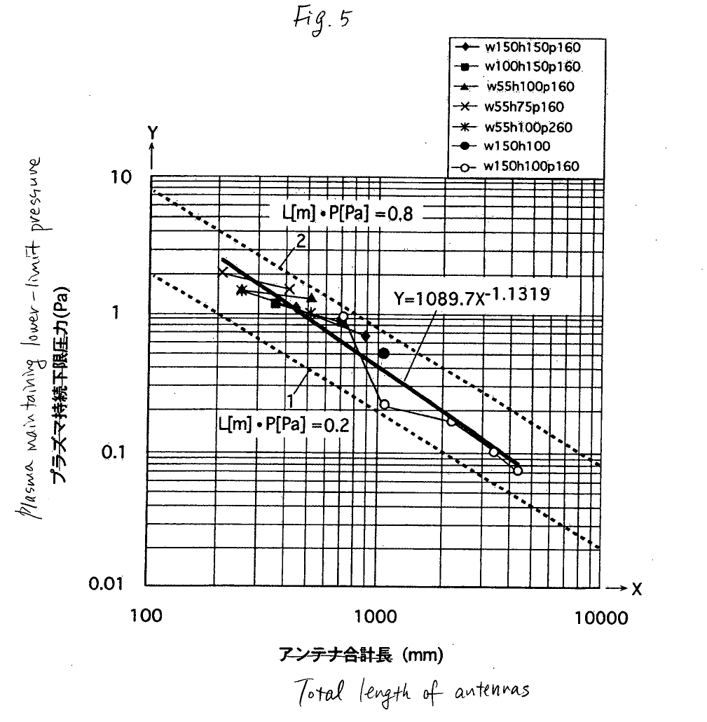

In the case where two antennas were used, as shown in FIGS. 2 and 3(A), the antennas 2 were adjacently arranged in the same plane and in a series manner, and an electric power was supplied to the adjacent end portions 21.

In the case where three antennas were used, as shown in FIG. 3(B), the antennas 2 were sequentially adjacently in the same plane and in a series manner, and, with respect to one set of adjacent antennas 2, an electric power was supplied to the adjacent end portions 21, and, with respect to the remaining antenna 2, to the end portion 21 which was outermost placed.

Similarly, FIG. 3(C) shows the antenna arrangement and power supply portions in the case where six antennas are used, FIG. 3(D) shows the antenna arrangement and power supply portions (see thick arrows) in the case where nine antennas are used, and FIG. 3(E) shows the antenna arrangement and power supply portions (see thick arrows) in the case where twelve antennas are used. In the case of six, nine, and twelve antennas, the pitch interval Q of adjacent antenna rows was 340 mm.

Relationships between the number of antennas and the plasma maintaining lower-limit pressure which were obtained in the experiments are collectively shown in FIG. 4.

In FIG. 4, character and numeral strings are enclosed by a square in the right side. For example, w150h150p160 means that the width w of one antenna is 150 mm, the height h in the chamber 1 is 150 mm, and the pitch interval p of adjacent antennas in the case where plural antennas are used is 160 mm. The other strings have similar meanings. Only one antenna (w150h150) indicated by a black circle was used.

As shown in FIG. 4, a tendency in which plasma is maintained more easily as the number of antennas is larger was obtained (from a comparison between the case of one antenna and that of two antennas in FIG. 4, and comparisons among the cases of three, six, nine, and twelve antennas indicated by white circles).

Furthermore, a tendency in which plasma is maintained more easily as the sizes (whole lengths) of antennas are larger was obtained (from a comparison among, in the case of the same number of antennas, w55h75, w55h100, w100h150, and w150h150 in FIG. 4).

The plasma maintaining characteristics which were obtained by the experiment depend on the number and sizes of antennas, and the plasma generating pressure in the chamber.

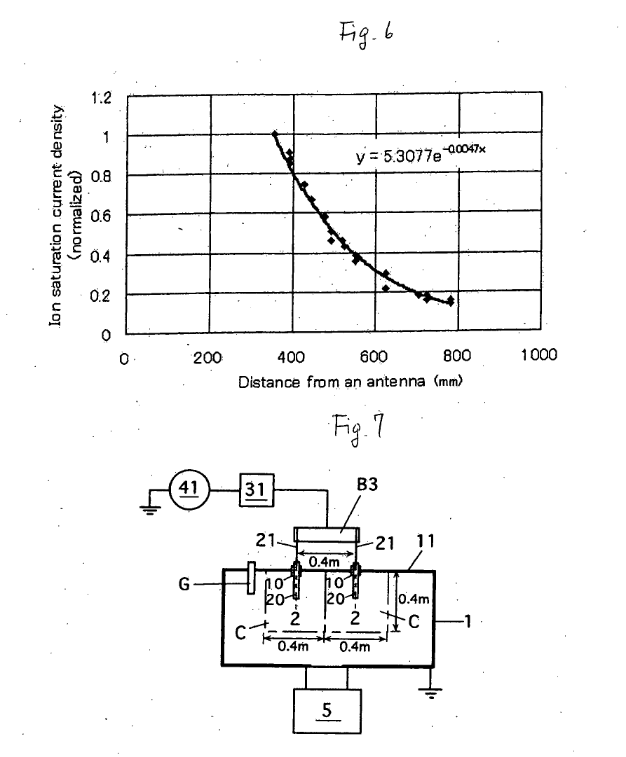

Results of the experiment were summarized with paying attention on the total length of the high-frequency antennas derived from the number and sizes of antennas in the plasma generating chamber (in other words, in a space of a constant size). As a result, it was found that, as shown in FIG. 5, there is an inverse proportional relationship between the plasma generating pressure P [Pa] and the total length L [m] of antennas in the chamber, i.e., the relationship indicated by the thick line in FIG. 5. In the inverse proportional relationship, PXL is constant.

From the above, it become apparent that, when the plasma generation pressure P [Pa] which is defined by the seed gas serving as the source of plasma, and the like is selected and determined, it is possible to obtain the total length of the antennas in a space of a constant size which is adequate for generating and maintaining plasma, or in other words which is just enough, and plasma can be generated in a correspondingly economical manner.

When the pressure P and the total length L [m] of antennas are selected in a region which is approximately above the thick line in FIG. 5, plasma can be generated and maintained. However, experiment data contain error, and there is a case where, even in a region below the thick line in FIG. 5, plasma can be generated and maintained depending on the seed gas serving as the source of plasma. When the pressure P and the total length L of antennas are determined in a region which is above the broken line 1 satisfying L×P=0.2, so as to include the region below the thick line, there arises no practical problem.

When the pressure P and the total length L of antennas are determined in the region which is above the broken line 1 satisfying L×P=0.2, however, there is a case where L is unnecessarily large. From an economic viewpoint, it is preferable to determine the pressure P and the total length L of antennas so as to be in a region which is below the broken line 2 satisfying about L×P=0.8.

Therefore, the total length L [m] of antennas in a constant space is requested to be approximately in a range of (0.2/P)<L<(0.8/P).

The experiment was performed with using hydrogen gas as the seed gas. Also when the seed gas is a noble gas such as Ar gas, silane gas, methane gas, nitrogen gas, oxygen gas, or the like, the physical quantities (lengths) of the high-frequency antennas can be determined with applying the relational expression of (0.2/P)<L<(0.8/P).

Next, the finding that high-frequency antennas can be distributed while setting a cubic space having a side of 0.4 [m] as a unit will be described.

The distribution density of inductively coupled plasma which is maintained by one low-inductance high-frequency antenna was checked. As a result, it was found that the plasma density can be well approximated by a function in which the density exponentially attenuates in accordance with the distance from the antenna.

The plasma density distribution was investigated in the following manner. One portal antenna (having a width of 150 mm, and a height of 150 mm) was hung from a ceiling wall of a plasma generating chamber. Langmuir probes were placed at positions of the bottom of the plasma generating chamber which are separated from the antenna by various distances (more correctly, various distances from the center point of a rectangular plane enclosed by the portal antenna) X [m]. Hydrogen gas was introduced into the plasma generating chamber to set the pressure in the chamber to 1.8 Pa. A high-frequency electric power (13.56 MHz, 1,000 W) was applied to the hydrogen gas to generate inductively coupled plasma. An ion saturation current density [A/cm²] which is measured by the Langmuir probes was obtained as a measurement value that is proportional to the plasma density. A relationship between the ion saturation current density and the distance X [m] from the antenna was obtained. FIG. 6 shows results of the

When the plasma density is indicated by N, and the distance from the antenna is indicated by X [m], the plasma density is approximated by N ∝ exp (−X/r). Since 1/r=0.0047 in the approximation function of FIG. 6, the scale factor r of the exponential attenuation function is r≈200 mm (about 0.2 m).

From the view point of uniformity of the plasma density distribution, the arrangement of antennas in a process chamber for plasma CVD with respect to a substrate of 1,100×1,500 mm was studied by obtaining the plasma density distribution by linear superposition with using characteristics of the density distribution of plasma which is maintained by the one antenna. In the case where the density of plasma which is maintained by one antenna is well approximated by a function in which the density exponentially attenuates in accordance with the distance from the antenna, a tendency in which, when the interval of antennas is increased, the plasma density distribution becomes nonuniform was obtained.

Examples of a specific arrangement pitch of antennas and uniformity of the plasma density are as follows.

| Arrangement pitch of antennas | Uniformity of plasma density |
|---|---|
| 300 mm | ±2% |
| 400 mm | ±4% |
| 450 mm | ±5.5% |

In the thin film formation by plasma CVD, usually, the plasma density is requested to have uniformity of about ±5%. Also in a plasma process other than the thin film formation, the plasma density is often requested to have uniformity of about ±5%. Therefore, it is usually preferable to set the pitch interval of antennas to about 400 mm or shorter. It can be said that, in order that inductively coupled plasma which is uniform as far as possible is generated while approximately maintaining such a pitch interval of antennas, a cubic space having a side of about 0.4 [m] is used as a unit, and a high-frequency antenna is disposed in the cubic space (typically, in a middle portion thereof).

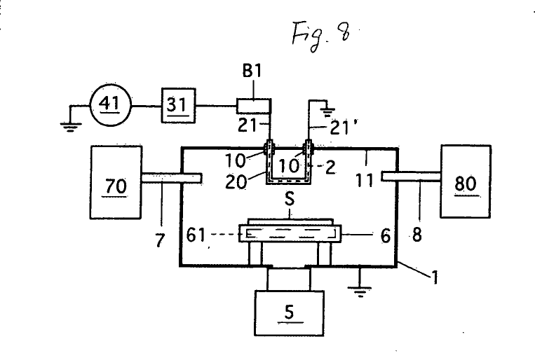

In the above-described plasma generating apparatus, in the case where two high-frequency antennas are to be used, they are arranged so as to be adjacently arranged in the same plane and in a series manner. Alternatively, as shown in FIG. 7, antennas may be arranged in parallel so as to be opposed to each other. Also when three or more antennas are used, they may be sequentially arranged in parallel so that adjacent ones are opposed to each other.

Further, in the above-described plasma generating apparatus, as shown in FIGS. 1 and 2, one high-frequency antenna is disposed in each of the cubic space. Alternatively, plural high-frequency antennas may be disposed in one cubic space having a side of 0.4 [m]. In this case, the total length L [m] of the high-frequency antennas in the cubic space is set in a range which satisfies the relationships of (0.2/P)<L<(0.8/P).

Various plasma processing apparatuses can be provided by using the above-described plasma generating apparatus. For example, it is possible to provide a plasma CVD apparatus; an apparatus which sputters a sputter target under plasma to form a film; an etching apparatus using plasma; an apparatus which extracts ions from plasma to perform ion implantation or ion doping; and an apparatus which uses such an apparatus and produces various semiconductor devices (for example, thin film transistors used in a liquid crystal device or the like), material substrates for such semiconductor devices, and the like.

FIG. 8 shows an example of a plasma CVD apparatus in which the plasma generating apparatus shown in FIG. 1 is used. The plasma CVD apparatus of FIG. 8 is configured in the following manner. The plasma generating chamber 1 of the plasma generating apparatus of FIG. 1 serves also as a film forming chamber. A holder 6 (incorporating a heater 61) for a substrate S on which a film is to be formed is placed in the chamber 1. Gas introducing pipes 7, 8 are used as a gas introducing section. A monosilane gas supplying apparatus 70 is connected to the pipe 7, and a hydrogen gas supplying apparatus 80 to the pipe. A silicon thin film can be formed on the substrate S.

The invention can be used in various fields in which a desired process is applied on a workpiece under plasma.

What is claimed is:

1. A method of generating plasma, comprising steps of:
allocating and disposing one or more high-frequency antennas, which applies a high-frequency electric power to a gas in a plasma generating chamber, in one cubic space having a side of 0.4 [m] in the plasma generating chamber or in each of plural cubic spaces, each having a side of 0.4 [m], adjacent ones of the plural cubic spaces being continuous to each other without forming a gap therebetween; and
setting a total length L [m] of the high-frequency antennas in each of said cubic spaces in a range which satisfies relationships of (0.2/P)<L<(0.8/P) with respect to an inductively coupled plasma generation pressure P [Pa] that is set in the plasma generating chamber.

2. The method according to claim 1, wherein plural high-frequency antennas are allocated and disposed in one cubic space or in each of plural cubic spaces, and a total length L [m] of the high-frequency antennas in each of said cubic spaces is set in the range which satisfies relationships of (0.2/P)<L<(0.8/P).

3. A plasma generating apparatus comprising:
a plasma generating chamber; and
one or more high-frequency antennas, which applies a high-frequency electric power to a gas in the plasma generating chamber, and is allocated and disposed in one cubic space having a side of 0.4 [m] in the plasma generating chamber or in each of plural cubic spaces, each having a side of 0.4 [m], adjacent ones of the plural cubic spaces being continuous to each other without forming a gap therebetween,
wherein a total length L [m] of said high-frequency antennas in each of the cubic spaces is set in a range which satisfies relationships of (0.2/P)<L<(0.8/P) with respect to an inductively coupled plasma generation pressure P [Pa] that is set in said plasma generating chamber.

4. The apparatus according to claim 3, wherein plural high-frequency antennas are allocated and disposed in one cubic space or in each of plural cubic spaces, and a total length L [m] of the high-frequency antennas in each of said cubic spaces is set in the range which satisfies relationships of (0.2/P)<L<(0.8/P).

5. A plasma processing apparatus which applies a desired process on a workpiece under plasma, comprising a plasma generating apparatus according to claim 3.
